(19) United States
(12) Patent Application Publication
(10) Pub. No.: US 2006/0054349 A1
(43) Pub. Date: Mar. 16, 2006

(54) Cof film carrier tape and its manufacturing method

(75) Inventor: Yutaka Iguchi, Shinagawa-ku (JP)

Correspondence Address: SUGHRUE MION, PLLC, 2100 PENNSYLVANIA AVENUE, N.W., SUITE 800, WASHINGTON, DC, 20037, US

(73) Assignee: MITSUI MINING 7 SMELTING CO., LTD., TOKYO JAPANY (JP)

(21) Appl. No.: 10/519,144

(22) PCT Filed: Jun. 23, 2003
(86) PCT No.: PCT/JP03/07916

§ 371 Date: Dec. 27, 2004

(30) Foreign Application Priority Data
Jun. 26, 2002 (JP) 2002-18690

(51) Int. Cl. H05K 1/03

(52) U.S. Cl. 174/255

(57) ABSTRACT

To provide a COF film carrier tape which enables smooth conveyance of insulating film during a production step and prevents production failures, and to provide a method for producing the COF film carrier tape.

In a COF film carrier tape including a continuous insulating film 12, a wiring pattern 21 formed of a conductor layer 11 provided on a surface of the insulating film 12, and a row of sprocket holes 22 along opposite longitudinal edges of the wiring pattern 21 on which electronic devices are to be mounted, a center section of the insulating layer 12 other than opposite longitudinal edges where the sprocket holes 22 are formed is provided with a support film 14 formed on another surface of the insulating film, which surface is opposite to the surface on which the wiring pattern 21 is provided.

### TECHNICAL FIELD

The present invention relates to a COF film carrier tape on which electronic devices such as ICs and LSIs are to be mounted, and to a method for producing the tape.

### BACKGROUND ART

Development of the electronics industry has been accompanied by sharp demand for printed-circuit boards for mounting electronic devices thereon, such as ICs (Integrated Circuits) and LSIs (Large-Scale Integrated circuits). Manufacturers have attempted to realize small-size, lightweight, and high-function electronic equipment, which has long been desired. To this end, manufactures have recently come to employ a film carrier tape for mounting electronic devices thereon, such as a TAB tape, a T-BGA tape, an ASIC tape, or a COF tape. Use of film carrier tapes has become increasing important, especially for manufacturers of personal computers, cellular phones, and other electronic equipment employing a liquid crystal display (LCD) that must have high resolution and small thickness, as well as a narrow screen-frame area.

Generally, such a film carrier tape for mounting electronic devices thereon is produced by continuously conveying a long insulating layer having sprocket holes provided on either lateral side and forming a plurality of wiring patterns and other elements on the insulating layer.

Meanwhile, there has arisen demand for considerably reducing the thickness of such a film carrier tape itself for mounting electronic devices thereon, in order to keep pace with a trend for downsizing of electronic devices. Thus, in recent years, a film carrier tape employing a relatively thin insulating layer has been proposed.

However, the aforementioned film carrier tape for mounting electronic devices thereon has the drawback that a thin insulating layer causes deformation or breakage during conveyance of the tape, since wiring patterns and similar elements are formed on the insulating layer while the layer is continuously conveyed. In addition, the film carrier tape causes deformation of sprocket holes during conveyance, since the mechanical strength around the sprocket holes cannot be sufficiently secured. Thus, the film carrier tape also has drawbacks that wiring patterns, solder resist patterns, etc. cannot be formed on predetermined positions with high precision and that electronic parts cannot be mounted with high precision.

In order to overcome the aforementioned drawbacks, some approaches have been proposed. Japanese Patent Application Laid-Open (kokai) No. 2-91956 discloses a tape structure in which a dummy wiring portion is provided around each sprocket hole so as to maintain mechanical strength around the sprocket hole. Japanese Patent Application Laid-Open (kokai) No. 11-297767 discloses a technical approach in which a backing film is affixed to the backside of a resin film opposite the surface on which copper foil is formed. Japanese Patent Application Laid-Open (kokai) No. 2000-223795 discloses a method including forming sprocket holes in a base film provided with a support film and peeling off the support film, and dummy wiring portions on the base film.

However, the aforementioned method also has a drawback. According to the method, a support film is affixed to the base film by the mediation of a tacky layer. In this case, when sprocket holes are formed in the base film, the support film is exfoliated at edge portions of the holes. To the exfoliated portions, a treatment liquid used in a subsequent chemical post-treatment process is transferred, and remains in the portions, thereby impairing the process and increasing failure rate of the products.

In order to prevent exfoliation of the support film at edge portions of the sprocket holes during formation of the holes, the tackiness of the tacky layer is increased. In this case, however, stress remains in the base film during peeling of the support film after formation of sprocket holes, and the stress causes the products to curl up, which is also problematic.

Meanwhile, when polyester film, which is a relatively inexpensive material, is employed as a support film, the support film is thermally shrunk or deformed during heat treatment-steps (e.g., a-whisker suppressing step after tin-plating and a solder resist curing step). As a result, positioning failure and abnormal conveyance due to warpage during production of COF film carrier tape occur, which are also problematic.

### DISCLOSURE OF THE INVENTION

In view of the foregoing, an object of the present invention is to provide a COF film carrier tape which enables smooth conveyance of insulating film during a production step and prevents production failures. Another object of the invention is to provide a method for producing the COF film carrier tape.

In order to attain the aforementioned objects, a first mode of the present invention provides a COF film carrier tape including a continuous insulating film, a wiring pattern formed of a conductor layer provided on a surface of the insulating film, and a row of sprocket holes provided on either lateral side of the wiring pattern on which electronic devices are to be mounted, characterized in that a center section of the insulating layer other than opposite longitudinal edges where the sprocket holes are formed is provided with a support film formed on another surface of the insulating film, which surface is opposite to the surface on which the wiring pattern is provided.

According to the first mode, the center (in a width direction) portion of the insulating layer is provided with a support film. Thus, problematic deformation or breakage of the insulating layer during conveyance of the tape carried out in a production step can be prevented. Since the support film does not cover the opposite longitudinal edges, incidental exfoliation of the support film at hole edge portions during formation of sprocket holes can be avoided. In addition, since deformation of the center portion can be avoided, conveyance of the tape by means of sprockets can be reliably performed.

A second mode of the present invention is drawn to a specific embodiment of the COF film carrier tape of the first mode, wherein the row of sprocket holes are provided with a dummy wiring portion surrounding the holes.

According to the second mode, the dummy wiring portion provided after formation of sprocket holes facilitates reliable conveyance of the tape performed in a subsequent procedure.

A third mode of the present invention is drawn to a specific embodiment of the COF film carrier tape of the second mode, wherein the dummy wiring portion is provided in the form of discrete islands each surrounding a sprocket hole.

According to the third mode, variation in strength of the COF film carrier tape having a slip-like dummy wiring portion, falling of metallic powder produced through contact between the dummy wiring portion and a guide, etc. and other problems can be avoided.

A fourth mode of the present invention is drawn to a specific embodiment of the COF film carrier tape of the third mode, wherein the tape has a predetermined distance between a longitudinal edge of the insulating layer and a longitudinal edge of the dummy wiring portion.

According to the fourth mode, the problem of falling metallic powder produced through contact between the dummy wiring portion and a guide, etc. can be more effectively prevented, since the dummy wiring portion does not extend to the longitudinal edge of the insulating layer.

A fifth mode of the present invention is drawn to a specific embodiment of the COF film carrier tape of any of the first to fourth modes, wherein the support film has a thickness which is equal to or smaller than that of the insulating layer.

According to the fifth mode, problematic deformation/shrinkage of the support film can be avoided by virtue of the provision of the support film thinner than the insulating layer.

A sixth mode of the present invention is drawn to a specific embodiment of the COF film carrier tape of the fifth mode, wherein the support film has a thickness of 25 to 50 μm.

According to the sixth mode, the support film is relatively thin. Thus, even when thermal deformation or similar deformation of the support film occurs, the COF film carrier tape itself is unlikely to be affected.

A seventh mode of the present invention provides a method for producing a COF film carrier tape including a continuous insulating film, a wiring pattern formed of a conductor layer provided on a surface of the insulating film, and a row of sprocket holes provided on either lateral side of the wiring pattern on which electronic devices are to be mounted, characterized in that the method comprises

a step of attaching a support film to a center section of the insulating layer other than opposite longitudinal edges where the sprocket holes are to be formed, the support film being formed on another surface of the insulating film, which surface is opposite to the surface on which the wiring pattern is provided;

a step of forming the sprocket holes in the opposite longitudinal edges; and

a step of forming the wiring pattern as well as a dummy wiring portion surrounding the row of sprocket holes by forming a resist pattern on the conductor layer and etching the conductor layer.

According to the seventh mode, the center (in a width direction) portion of the insulating layer is provided with a support film. Thus, problematic deformation or breakage of the insulating layer during conveyance of the tape in a production step can be prevented. Since the support film does not cover the opposite longitudinal edges, incidental exfoliation of the support film at hole edge portions during formation of sprocket holes can be avoided. In addition, since deformation of the center portion can be avoided, conveyance of the tape by the mediation of sprocket holes can be reliably performed.

An eighth mode of the present invention is drawn to a specific embodiment of the method of the seventh mode for producing a COF film carrier tape, wherein the dummy wiring portion is provided in the form of discrete islands each surrounding a sprocket hole.

According to the eighth mode, variation in strength of the COF film carrier tape having a slip-like dummy wiring portion, falling of metallic powder produced through contact between the dummy wiring portion and a guide, and other problems can be avoided.

A ninth mode of the present invention is drawn to a specific embodiment of the method of the seventh or eighth mode for producing a COF film carrier tape, wherein the method further comprises, after formation of the dummy wiring portion, a step of peeling off the support film.

According to the ninth mode, reliable conveyance of the tape is secured during mounting electronic elements or a similar process, even after formation of the dummy wiring portion and peeling of the support film.

As described hereinabove, according to the present invention, a center section of the insulating layer other than opposite longitudinal edges where the sprocket holes are formed is provided with a support film. Thus, there can be provided a COF film carrier tape which enables smooth conveyance of insulating film during a device production step and prevents production failures, and a method for producing the COF film carrier tape.

### BRIEF DESCRIPTION OF THE DRAWINGS

FIG. 1(a) and FIGS. 1(b) and 1(c) are a plan view and cross-sectional views, respectively, that schematically show a COF film carrier tape according to one embodiment of the present invention.

FIG. 2 is a cross-sectional view of an exemplary laminate film for producing a COF film carrier tape employed in one embodiment of the present invention.

FIG. 3 is a schematic cross-sectional view showing another exemplary COF film carrier tape according to one embodiment of the present invention.

FIG. 4 is a cross-sectional view illustrating production steps of a COF film carrier tape according to one embodiment of the present invention.

FIG. 5 is a view that schematically shows a COF film carrier tape according to another embodiment of the present invention.

### BEST MODES FOR CARRYING OUT THE INVENTION

The COF laminated film of the present invention comprises a conductor layer and an insulating layer. Examples of such laminate film include a laminate film prepared by sputtering a bond-improving layer (e.g., Ni) on an insulating film (e.g., polyimide film) and plating copper on the bond-improving layer; a casting-type laminate film prepared by applying polyimide to copper foil; and a laminate film prepared through hot-press-adhesion of an insulating layer onto copper foil by the mediation of a thermoplastic or thermosetting resin. In the present invention, any of these laminate films may be employed. Although the conductor layer may be formed from a metal other than copper; e.g., gold or silver, and a copper layer is generally employed. Any type of copper foil such as electrodeposited copper foil or rolled copper foil may be used. Generally, the conductor layer has a thickness of 1 to 70 μm, preferably 5 to 35 μm.

The insulating layer may be formed from, other than polyimide, a polymeric material such as polyester, polyamide, polyether-sulfone, or liquid crystalline polymer. Of these, an aromatic polyimide (all repeating units being aromatic) having a biphenyl skeleton is preferred. When polyimide film is employed, the thickness of the insulating layer is about 5 to 50 μm, preferably about 25 to 40 μm.

The support film employed in the present invention may be formed from polyester film, polyimide film, etc. The thickness of the film employed is preferably equal to or less than that of the insulating layer. A support film having a thickness of about 25 μm is preferably used, and one having a thickness of about 5 μm to 50 μm may also be used.

No particular limitation is imposed on the method of bonding the support film to the insulating layer, and a tacky layer or an adhesion layer is applied onto at least one of the support film or the insulating layer, followed by bonding. Alternatively, a support film having in advance a tacky layer or an adhesion layer may be bonded to the insulating layer. After simply binding the support film and the insulating layer, the two layers may be securely bonded through press-adhesion or hot-press-adhesion. The bonding method is not particularly limited.

Hereafter, embodiments of the laminate film for producing a COF film carrier tape and the COF film carrier tape of the present invention will be described.

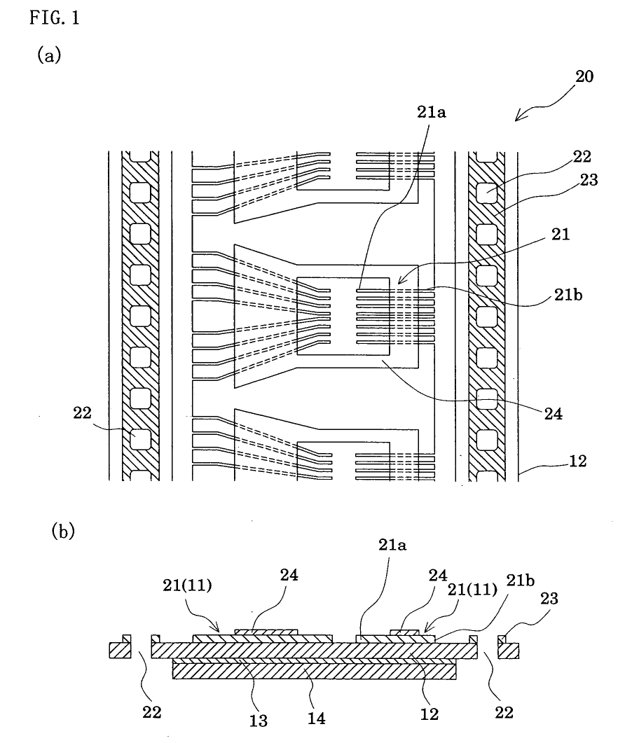

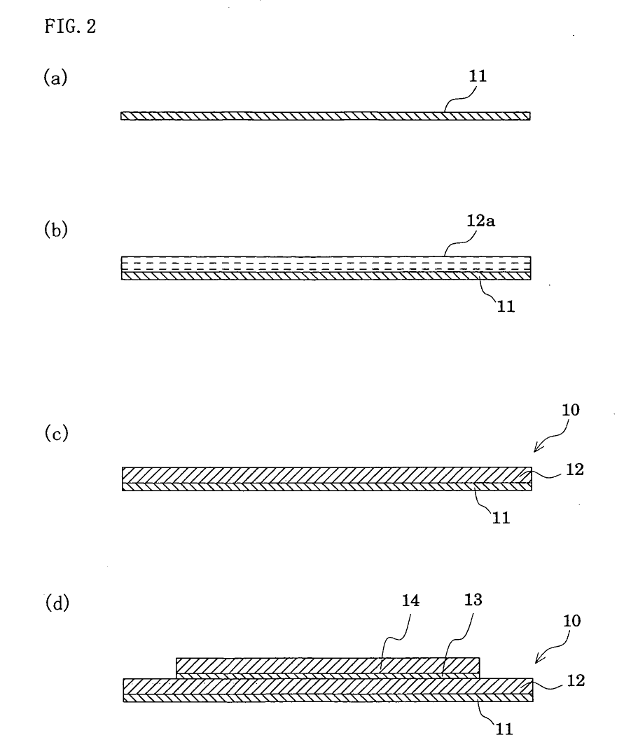

FIG. 1 shows a COF film carrier tape film carrier tape according to one embodiment of the invention, and FIG. 2 shows the laminate film for producing a COF film carrier tape. The COF film carrier tape 20 according to the present embodiment (shown in FIGS. 1(a) and 1(b)) is produced from a laminate film 10 for producing a COF film carrier tape. As shown in FIG. 2, the laminate film includes a conductor layer 11 (copper foil) and an insulating layer 12 (polyimide film), and a support film 14 is affixed by the mediation of a tacky layer 13 to the surface of the insulating layer 12 opposite the conductor layer 11. FIG. 2 illustrates an exemplary method for producing the laminate film 10 for producing a COF through the coating method. In this method, a polyimide precursor resin composition containing a polyimide precursor and varnish is applied to a conductor layer 11 (copper foil, FIG. 2(a)), to thereby form a coating layer 12a (FIG, 2(b); the solvent is removed by drying; and the coating layer is wound. The wound coating layer is heated in an oxygen-purged curing furnace for imidization, to thereby form the insulating layer 12 (FIG. 2(c)). Subsequently, a support film 14 having the tacky layer 13 is bonded to the surface of the insulating layer 12 opposite to the conductor layer 11, and the two layers are securely bonded through hot-press-adhesion or a similar method (FIG. 2(d)). Notably, the support film 14 is narrower than the insulating layer 12 and is provided only to a center section of the insulating layer 12 other than opposite longitudinal edges.

The COF film carrier tape 20 includes a wiring pattern 21 formed by patterning the conductor layer 11 and a row of sprocket holes 22 along opposite longitudinal edges of the wiring pattern 21. The wiring pattern 21 has dimensions almost corresponding to those of electronic devices to be mounted, and is provided on a surface of the insulating layer 12 in a continuous manner. In addition, a dummy wiring portion 23, which is electrically isolated from the wiring pattern 21, is provided so as to surround sprocket holes 22. On the wiring pattern 21, a solder resist layer 24 is formed through screen printing of a solder resist coating solution. At least the area corresponding to an inner lead 21a of the wiring pattern 21 is plated with a plating layer which is able to be joined, through gold-tin eutectic joining or gold-gold hot-pressing, to a gold bump of an electronic device. Examples of the plating layer include tin plating, tin alloy plating, gold plating, gold alloy plating, and other plating layers.

The support film 14 supports a center section (in a width direction) of the insulating layer 12 during the aforementioned step of producing the COF film carrier tape 20. However, since the support film 14 does not cover the areas to be provided with sprocket holes 22, problems such as exfoliation of a portion of the support film during formation of sprocket holes 22 are avoided. In other words, there can be avoided the problem that a treatment liquid used in a subsequent chemical treatment process is transferred to exfoliated portions and remains in the portions, thereby impairing the process and increasing failure of the products.

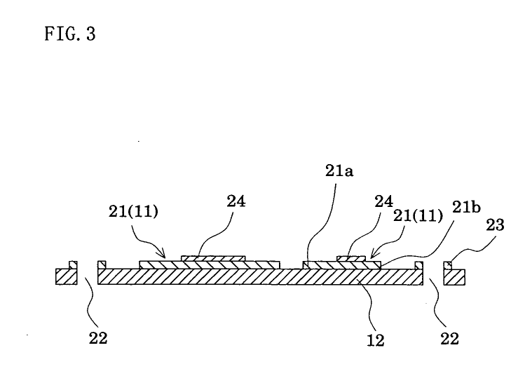

The COF film carrier tape 20 may be used while the support film 14 remains attached thereto. Alternatively, as shown in FIG. 3, the support film 14 is peeled off from the tape, and the tape having no support film may also be used in a step of mounting electronic devices.

After peeling of the support film 14, a portion having a reduced thickness for facilitating folding the tape may be provided to an area corresponding to each wiring pattern 21 through laser processing or a similar method.

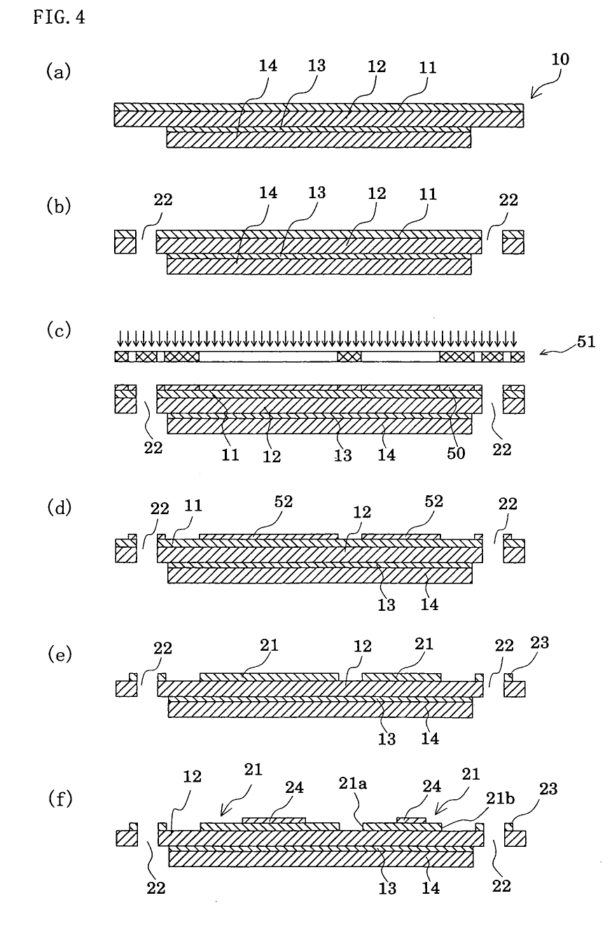

One exemplary method for producing the aforementioned COF film carrier tape will next be described with reference to FIG. 4.

First, as shown in FIG. 4(a), a COF laminate film 10 is provided. Then, as shown in FIG. 4(b), sprocket holes 22 are perforated through a conductor layer 11 and an insulating layer 12 by, for example, punching. This perforation of the sprocket holes 22 may be carried out from the top side of the insulating layer 12 or from the bottom side of the insulating layer 12. Subsequently, as shown in FIG. 4(c), a photoresist coating layer 50 is formed on the conductor layer 11 through a conventional photolithographic method by applying a photoresist material coating solution (e.g., a negative type) to a pattern-forming region in which the wiring pattern 21 is to be formed. Needless to say, a positive type photoresist material may also be used. The insulating layer 12 is positioned by means of positioning pins inserted in the sprocket holes 22. After positioning of the insulating layer 12, the photoresist coating layer 50 is exposed through a photomask 51 and developed, to thereby perform patterning, thereby forming a resist pattern 52 as shown in FIG. 4(d). In addition to the wiring pattern, a pattern for forming a dummy wiring portion is also formed during the above patterning. Then, with the resist pattern 52 serving as a mask pattern, the conductor layer 11 is dissolved and removed by an etching solution, whereupon the resist pattern 52 is dissolved and removed by an alkaline solution or a similar material. As a result, a wiring pattern 21 and a dummy wiring portion 23 are formed as shown in FIG. 4(e). As shown in FIG. 4(f), a solder resist layer 24 is formed through, for example, screen printing, on an area other than the inner lead 21a and an outer lead 21b.

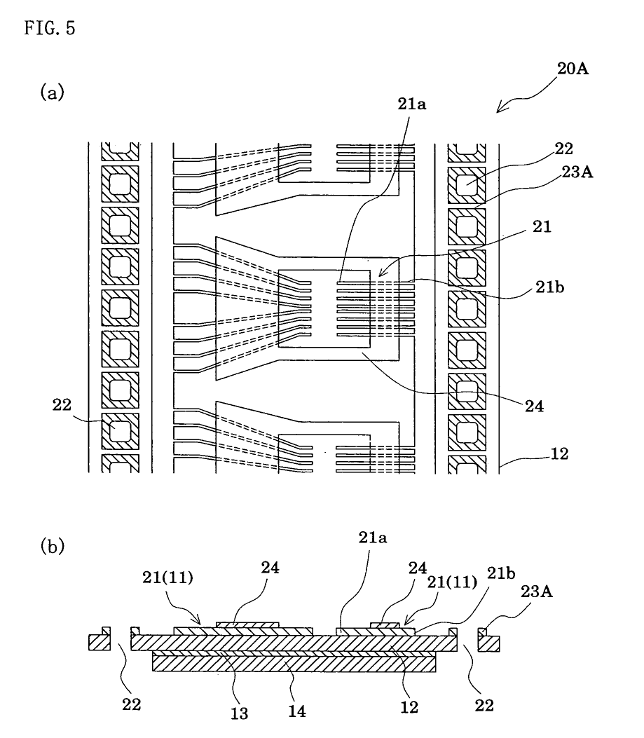

In the aforementioned production steps, the dummy wiring portion 23 is provided in the slip-like form. However, no particular limitation is imposed on the form of the dummy wiring portion, and the dummy wiring portion may be provided in the form of discrete islands each surrounding a sprocket hole provided along the tape in the conveyance direction. FIG. 5 shows this feature. In the COF film carrier tape 20A, a dummy wiring portion 23A is provided in the form of discrete islands each surrounding a sprocket hole 22.

In the aforementioned step, the dummy wiring portion is simultaneously formed in the step of forming the wiring pattern 21. However, the dummy wiring portion may be provided separately in a step other than the step of forming the wiring pattern 21 through a method such as the transfer method for partially transferring the wiring.

According to the present invention, a section of the insulating layer other than opposite longitudinal edges where the sprocket holes are formed is provided with a support film. Thus, incidental deformation of the film itself as well as problematic exfoliation of the support film during formation of sprocket holes can be prevented.

Conventionally, when polyester film, which is a relatively inexpensive material, is employed as a support film, the support film is thermally shrunk or deformed during heat treatment steps (e.g., a whisker suppressing step after tin-plating and a solder resist curing step). As a result, positioning failure and abnormal conveyance due to warpage during production of COF film carrier tape occur, which are problematic. However, through employment of a relatively thin film (e.g., a support film thinner than the insulating film) in the present invention, the aforementioned problems such as thermal deformation can be prevented.

When a dummy wiring portion is provided during a production step, conveyance failure of the film carrier tape during subsequently carried out mounting of electronic devices and other operations can be prevented even after peeling of the support film.

Particularly when the dummy wiring portion is provided in the form of discrete islands each surrounding a sprocket hole, rigidity of the insulating layer can be enhanced such a level as to attain reliable conveyance. In this case, the rigidity is not excessively enhanced, and conveyance failure such as bending or deformation can be avoided.

The dummy wiring portion is provided such that the dummy wiring portion does not extend to the longitudinal edge of the insulating layer and that the tape has a predetermined distance between a longitudinal edge of the insulating layer and a longitudinal edge of the dummy wiring portion. As a result, short circuit of the wiring pattern or other failures can be prevented. More specifically, there can be prevented failures such as short circuits caused by contact of the wiring pattern with metal dust (metal powder), which is generated through contact between the dummy wiring portion and a guide or similar apparatus provided along the conveyance route during conveyance of the insulating layer in film carrier tape production.

In addition, since the rigidity of the entire tape is not excessively enhanced, the tape itself can flexibly follow the conveyance route even when the route is curved, thereby attaining favorable conveyance.

### EXAMPLE 1

On a surface of an insulating layer (polyimide film (thickness: 25 μm), Kapton EN 25, commercial product of Toray du Pont), a bond-improving layer was formed through sputtering, and a conductive layer (a copper plating layer) was provided on the bond-improving layer. The film was provided with a support film formed of polyester film (thickness: 50 μm) (Lumirror 50S10, product of Toray Industries, Inc.). The support film was provided on an area other than opposite longitudinal edges where the sprocket holes are to be formed. Subsequently, sprocket holes, a wiring pattern, a dummy wiring portion, and a solder resist layer were formed, to thereby provide a COF film carrier tape.

### EXAMPLE 2

The procedure of Example 1 was repeated, except that polyester film (thickness: 25 μm) (Lumirror 25S10, product of Toray Industries, Inc.) was used as the support film, to thereby provide a COF film carrier tape.

### COMPARATIVE EXAMPLE

The procedure of Example 1 was repeated, except that the support film having the same width as that of the insulating film was provided, to thereby provide a COF film carrier tape.

### TEST EXAMPLES

Each of the film carrier tape samples of the Examples and Comparative Example was observed to confirm remaining of the liquid employed in the processes between the support film and the insulating layer.

Percent tape shrinkage (%) of each sample was determined from the ratio of the tape length after provision of the solder resist layer to the tape length at an initial process stage.

Warpage of each film carrier tape sample was determined. Specifically, a film carrier tape sample (length: 100 mm) was placed on a base plate such that the support film faced upward while resting on the plate, and the height (h; mm) of the longitudinal edge was measured from the base plate. A height of 5 mm or more was rated “large,” and a height of less than 5 mm was rated “small.”

The results are shown in Table 1.

TABLE 1

| | Thickness | | Percent | |
|---|---|---|---|---|
| | of support | Residue of | shrinkage | |
| | film (μm) | liquid | (%) | Warpage |
| Example 1 | 50 | None | 0.15 | large |
| Example 2 | 25 | None | 0.08 | small |
| Comparative | 50 | Around | 0.17 | large |
| Example | | sprocket | | |
| | | holes | | |

As described hereinabove, the samples of Examples 1 and 2 did not exhibit exfoliation of the support film from the insulating layer during processes, since the area where sprocket holes were provided was not covered with the support film. In addition, no liquid remained. In contrast, the sample of Comparative Example exhibited exfoliation of the support film during formation of sprocket holes, and residue of liquid was observed to remain in the exfoliated portions. The residue of liquid was observes as dried white powder, since the tape underwent a dewatering step and a drying step.

Although the above support films have relatively large percent thermal shrinkage, the effect of thermal shrinkage was minimized by changing the thickness of the support film from 50 μm to 25 μm. In this case, warpage of the tape was found to be small.

1. A COF film carrier tape including a continuous insulating film, a wiring pattern formed of a conductor layer provided on a surface of the insulating film, and a row of sprocket holes provided on either lateral side of the wiring pattern on which electronic devices are to be mounted, characterized in that
a center section of the insulating layer other than opposite longitudinal edges where the sprocket holes are formed is provided with a support film formed on another surface of the insulating film, which surface is opposite to the surface on which the wiring pattern is provided.

2. A COF film carrier tape according to claim 1, wherein the row of sprocket holes are provided with a dummy wiring portion surrounding the holes.

3. A COF film carrier tape according to claim 2, wherein the dummy wiring portion is provided in the form of discrete islands each surrounding a sprocket hole.

4. A COF film carrier tape according to claim 3, wherein the tape has a predetermined distance between a longitudinal edge of the insulating layer and a longitudinal edge of the dummy wiring portion.

5. A COF film carrier tape according to claim 1, wherein the support film has a thickness which is equal to or less than that of the insulating layer.

6. A COF film carrier tape according to claim 2, wherein the support film has a thickness which is equal to or less than that of the insulating layer.

7. A COF film carrier tape according to claim 3, wherein the support film has a thickness which is equal to or less than that of the insulating layer.

8. A COF film carrier tape according to claim 4, wherein the support film has a thickness which is equal to or less than that of the insulating layer.

9. A COF film carrier tape according to claim 5, wherein the support film has a thickness of 25 to 50 μm.

10. A COF film carrier tape according to claim 6, wherein the support film has a thickness of 25 to 50 μm.

11. A COF film carrier tape according to claim 7, wherein the support film has a thickness of 25 to 50 μm.

12. A COF film carrier tape according to claim 8, wherein the support film has a thickness of 25 to 50 μm.

13. A method for producing a COF film carrier tape including a continuous insulating film, a wiring pattern formed of a conductor layer provided on a surface of the insulating film, and a row of sprocket holes provided on either lateral side of the wiring pattern on which electronic devices are to be mounted, characterized in that
the method comprises
a step of attaching a support film to a center section of the insulating layer other than opposite longitudinal edges where the sprocket holes are to be formed, the support film being formed on another surface of the insulating film, which surface is opposite to the surface on which the wiring pattern is provided;
a step of forming the sprocket holes in the opposite longitudinal edges; and
a step of forming the wiring pattern as well as a dummy wiring portion surrounding the row of sprocket holes by forming a resist pattern on the conductor layer and etching the conductor layer.

14. A method for producing a COF film carrier tape according to claim 13, wherein the dummy wiring portion is provided in the form of discrete islands each surrounding a sprocket hole.

15. A method for producing a COF film carrier tape according to claim 13, wherein the method further comprises, after formation of the dummy wiring portion, a step of peeling off the support film.

16. A method for producing a COF film carrier tape according to claim 14, wherein the method further comprises, after formation of the dummy wiring portion, a step of peeling off the support film.
